(19) United States
(12) Patent Application Publication
(10) Pub. No.: US 2024/0421030 A1
(43) Pub. Date: Dec. 19, 2024

(54) SEMICONDUCTOR DEVICE WITH ENHANCED THERMAL MITIGATION

(71) Applicant: Micron Technology, Inc., Boise, ID (US)

(72) Inventors: Bharat Bhushan, Taichung (TW); Amy R. Griffin, Boise, ID (US); Kunal R. Parekh, Boise, ID (US); Akshay N. Singh, Meridian, ID (US)

(21) Appl. No.: 18/674,664

(22) Filed: May 24, 2024

Related U.S. Application Data
(60) Provisional application No. 63/521,310, filed on Jun. 15, 2023.

(51) Int. Cl. H01L 23/373; H01L 23/00; H01L 23/29; H01L 23/31; H01L 25/00; H01L 25/065; H10B 80/00

(52) U.S. Cl. CPC H01L 23/373; H01L 23/291; H01L 23/3107; H01L 24/08; H01L 25/0652; H01L 25/50; H10B 80/00; H01L 2224/08145

(57) ABSTRACT

A semiconductor device is provided. The semiconductor device includes a logic die, a first plurality of stacked memory dies electrically coupled with the logic die at a first location above a back side surface of the logic die, a second plurality of stacked memory dies electrically coupled with the logic die at a second location above the back side surface of logic die, a first dielectric material disposed above the back side surface of the logic die and between the first plurality of stacked memory dies and the second plurality of stacked memory dies, and a dummy die disposed above the first dielectric material and coupled to the first plurality of stacked memory dies and the second plurality of stacked memory dies, wherein the dummy die is coupled to back side surfaces of the first plurality and second plurality of stacked memory dies through a second dielectric layer having dielectric-dielectric fusion bonding.

### CROSS-REFERENCE TO RELATED APPLICATION(S)

The present application claims priority to U.S. Provisional Patent Application No. 63/521,310, filed Jun. 15, 2023, the disclosure of which is incorporated herein by reference in its entirety.

### TECHNICAL FIELD

The present disclosure generally relates to semiconductor devices and more particularly relates to structures of semiconductor devices configured to enhance thermal mitigation.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they can be “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 illustrates a simplified schematic cross-sectional view of a semiconductor device.

FIG. 2 illustrates a simplified schematic cross-sectional view of another semiconductor device in accordance with an embodiment of the present technology.

FIGS. 3-9B illustrate simplified schematic perspective and cross-sectional views of a series of steps for fabricating semiconductor devices in accordance with an embodiment of the present technology.

FIG. 10 illustrates a method of making a semiconductor device in accordance with an embodiment of the present technology.

FIG. 11 illustrates a schematic view of a system that includes a semiconductor device assembly configured in accordance with an embodiment of the present technology.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the drawings, the same reference numerals used in different embodiments designate like or corresponding, but not necessarily identical, elements.

### DETAILED DESCRIPTION

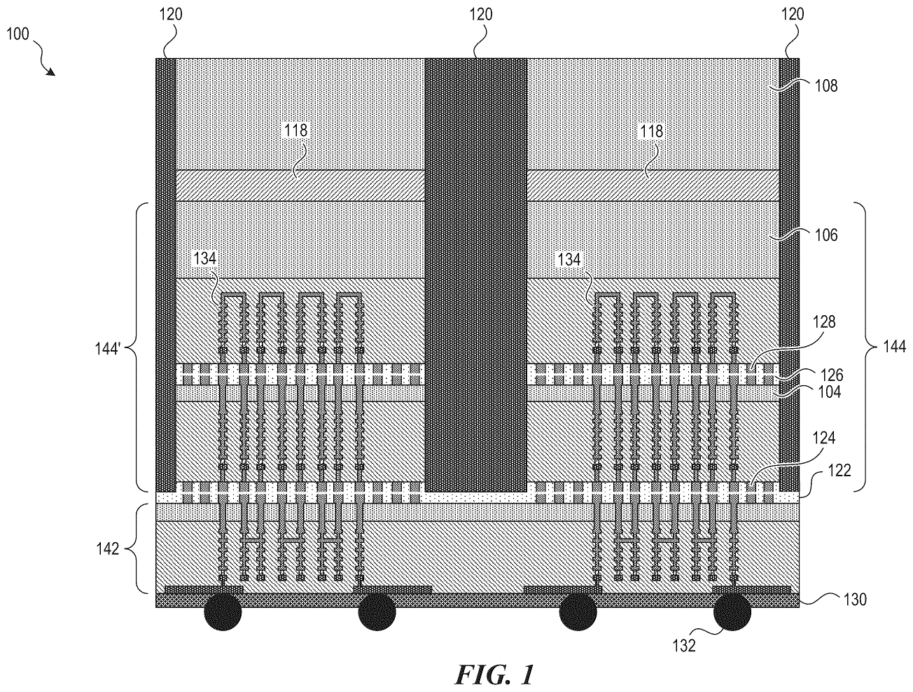

The demand for smaller and more compact semiconductor devices has led to integrated circuit designs in which components are stacked on top of each other, the stack being disposed on a common package substrate to form an assembly. Specifically, stacked semiconductor devices can enable multiple semiconductor dies to be stacked on top of one another to increase the number of circuit elements within a package without increasing its footprint. To produce a stacked semiconductor device, multiple wafers may be stacked together and diced into individual die stacks. Conventional assemblies of stacked integrated circuit components may include one or more dummy dies placed or formed on top of the stacked semiconductor dies to planarize the stacked semiconductor dies with other integrated circuit components included in the same packaging assembly. The dummy dies may be formed in a singulation process from a silicon wafer into a designed size and then coupled to the stacked semiconductor dies by flowing non-conductive filling materials therebetween. The stacked semiconductor dies as well as the one or more dummy dies may then be packaged into a packaged semiconductor device to be implemented within a larger electronic device. Some techniques, however, may struggle to produce large stacks of semiconductor dies due, for example, to the limitations of thermal mitigation. One such technique is shown by way of example in FIG. 1.

FIG. 1 illustrates a semiconductor device 100 that includes a first plurality of semiconductor dies 144 (e.g., memory dies) and a second plurality of semiconductor dies 144′ (e.g., memory dies) assembled onto a wafer of semiconductor dies 142 (e.g., logic dies). The first plurality of stacked semiconductor dies 144 and the second plurality of stacked semiconductor dies 144′ may be singulated from a stack of semiconductor wafers. The stack of semiconductor wafers may be created by bonding wafers that include a plurality of semiconductor dies (e.g., through wafer-wafer bonding). The wafers may be bonded in a front-to-back arrangement such that a front side (e.g., an active side) of a first wafer at which circuitry of the semiconductor dies is implemented is mounted to a back side (e.g., an inactive side) of a second wafer. One or more of the semiconductor wafers may include through-silicon vias (TSVs 134) that are exposed at the back side of the semiconductor wafers. The semiconductor wafers may be coupled through hybrid bonding. For example, the semiconductor wafers may be electrically coupled through interconnects (e.g., metal-metal interconnects) and bonded through a dielectric material (e.g., dielectric block 122 and 126). In aspects, the interconnects may be copper-copper (Cu—Cu) interconnects through contact pads 128 or 124. The dielectric material 122 and 126 may include any appropriate dielectric material, for example, silicon oxide, silicon nitride, silicon carbide, silicon carbon nitride, or the like.

Once the semiconductor wafers have been bonded into a stack, stacks of semiconductor dies can be singulated from the stack of wafers and assembled onto a wafer of semiconductor dies 1142. In this example, a top memory die 106 can be coupled to a core memory die 104 by wafer-wafer bonding of a first memory wafer and a second memory wafer and singulation the bonded wafers. The wafer of semiconductor dies 142 may include a plurality of semiconductor dies having a different arrangement than the semiconductor dies of the first plurality of stacked semiconductor dies 144 or the second plurality of stacked semiconductor dies 144′. For example, the wafer of semiconductor dies 142 may include logic dies, and the first plurality of stacked semiconductor dies 102 or the second plurality of stacked semiconductor dies 144′ may include memory dies. As a result, the wafer of semiconductor dies 142 may not be bonded with the stack of wafers through a wafer-wafer bond. Instead, the wafer of semiconductor dies 142 may be adhered to a carrier substrate 130 to help the device withstand processing, and the first plurality of stacked semiconductor dies 144 and the second plurality of stacked semiconductor dies 144′ may be electrically coupled to the wafer of semiconductor dies 142. After the pluralities of stacked semiconductor dies are assembled onto the wafer of semiconductor dies 142, a mold resin 120 may be disposed on the wafer of semiconductor dies 142 around the plurality of stacked semiconductor dies 144 and the plurality of stacked semiconductor dies 144′. In addition, solder balls 132 can be formed on a backside of the carrier substrate for electrical interconnection. The stacked semiconductor dies and the various semiconductor dies on the wafer of semiconductor dies 142 can then be diced, and the singulated stacks of semiconductor dies may be packaged into the semiconductor device 100.

The semiconductor device 100 also includes dummy dies 108 that are disposed above each one of first plurality of stacked semiconductor dies 144 or the second plurality of stacked semiconductor dies 144′. In this example, the dummy dies 108 are coupled to each one of first plurality of stacked semiconductor dies 144 or the second plurality of stacked semiconductor dies 144′ through the NCF layer 118. The NCF layer 118 may be made of epoxy-based materials, acrylic-based materials, and/or polyimide-based materials, providing robust electrical insulation between the dummy dies 108 and the pluralities of stacked semiconductor dies 144 and 144′. Here, the NCF layer 118 may have a thickness higher than a threshold value (e.g., 15 μm) to ensure a good adhesion. In addition, the NCF layer 118 may have a low thermal conductivity (e.g., 0.31-0.36 W/*(m·k)) due to the types of materials included in the NCF layer 118. The low thermal conductivity and thicker film profile of the NCF layer 118 make it challengeable to achieve good thermal mitigation in the semiconductor device 100.

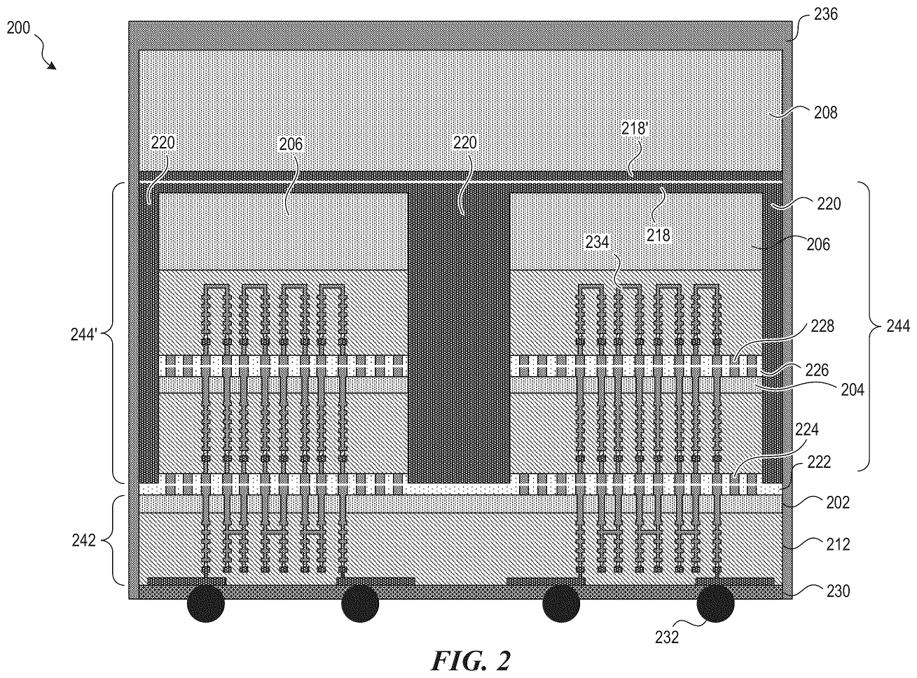

To address these drawbacks and others, various embodiments of the present technology provide semiconductor devices that include wafer to wafer (W2 W) front-to-back side bonding between dummy silicon dies and pluralities of stacked semiconductor dies. A semiconductor device is provided. The semiconductor device includes a logic die, a first plurality of stacked memory dies electrically coupled with the logic die at a first location above a back side surface of the logic die, a second plurality of stacked memory dies electrically coupled with the logic die at a second location above the back side surface of the logic die, a first dielectric material disposed above the back side surface of the logic die and between the first plurality of stacked memory dies and the second plurality of stacked memory dies, and a dummy die disposed above the first dielectric material and coupled to the first plurality of stacked memory dies and the second plurality of stacked memory dies, wherein the dummy die is coupled to back side surfaces of the first plurality and the second plurality of stacked memory dies through a second dielectric layer having dielectric-dielectric fusion bonding. An example semiconductor device is shown in FIG. 2.

FIG. 2 illustrates a semiconductor device 200 that includes a first plurality of semiconductor dies 244 (e.g., memory dies) and a second plurality of semiconductor dies 244′ (e.g., memory dies) coupled onto a wafer of semiconductor dies 242 (e.g., logic dies). The first plurality of semiconductor dies 244 may be coupled (e.g., chip-wafer bonded) onto the wafer of semiconductor dies 206 at a first semiconductor die (e.g., at a first lateral location). The wafer of semiconductor dies 242 may be assembled onto a carrier substrate 230 (e.g., through an adhesive or dielectric material) to enable the semiconductor device 200 to withstand processing. The carrier substrate 230 may include solder balls 232 on its back side to provide electrical interconnection. Here, the first plurality of stacked semiconductor dies 244 and the second plurality of stacked semiconductor dies 244′ may be singulated from a stack of semiconductor wafers. The stack of semiconductor wafers may be created by bonding wafers that include a plurality of semiconductor dies (e.g., wafer-wafer bonding). The wafers may be bonded in a front-to-back arrangement such that a front side (e.g., an active side) of a first wafer at which circuitry of the semiconductor dies is disposed is mounted to a back side (e.g., an inactive side) of a second wafer. One or more of semiconductor dies of the first plurality of stacked semiconductor dies 244 may include TSVs 234 that are exposed at the back side of the semiconductor dies. Contact pads 228 may be formed at the front side of the semiconductor dies and contact pads 224 may be formed at the exposed TSVs 234 at the front side of the semiconductor dies.

The semiconductor dies may electrically couple at the contact pads 228 and the contact pads 224 through interconnects. The semiconductor dies within the first plurality of stacked semiconductor dies 244 may be coupled through hybrid bonding. For example, the semiconductor wafers may be electrically coupled through interconnects 234 (e.g., metal-metal interconnects) and bonded through a dielectric material 222 or 226 (e.g., dielectric block). In aspects, the contact pads 224 and 228 may be copper-copper (Cu—Cu) interconnects. The dielectric material 222 or 226 may include any appropriate dielectric material, for example, silicon oxide, silicon nitride, silicon carbide, silicon carbon nitride, or the like. Given that the interconnects may be formed from wafer-wafer bonding, the interconnects between the contact pads 224 and 228 may be smaller than interconnects formed by chip-wafer or die-wafer bonding. In this example, the plurality of stacked semiconductor dies 244 includes a top semiconductor die 206 and a core semiconductor die 204, the top semiconductor die 206 being coupled to the core semiconductor die 204. The second plurality of semiconductor dies 244′ may be similarly fabricated and diced from a stack of semiconductor wafers. For example, the second plurality of stacked semiconductor dies 244′ may include a top semiconductor die and a core semiconductor die, the top semiconductor die being coupled to the core semiconductor die. The second plurality of semiconductor dies may be coupled to the wafer of semiconductor dies 242 at a second location above the back side surface of the wafer of semiconductor dies 242. A distance between the first location and the second location may range from 10 μm to 10 mm. Moreover, a dielectric material 220 can be disposed on the wafer of semiconductor dies 242 and between the first plurality of semiconductor dies 244 (e.g., memory dies) and a second plurality of semiconductor dies 244′. As shown, the dielectric material 220 can be filled between the pluralities of stacked semiconductor dies 244 and 244′ without any voids. Further, the dielectric material 220 can be also disposed above back side surface of the first plurality of semiconductor dies 244 (e.g., memory dies) and a second plurality of semiconductor dies 244′, forming a thin dielectric layer 218 there above with a thickness ranging from 10 nm to 1 μm and a planarized surface. Moreover, the first dielectric material 220 can be further disposed in edge region of the semiconductor device 200. The first dielectric material 220 may surround outer sidewalls of the first plurality and the second plurality of stacked memory dies 244 and 244′ facing towards the edge region of the semiconductor device 200.

In this example, the semiconductor device 200 may include a dummy die 208 that is disposed above the first plurality of semiconductor dies 244 and the second plurality of semiconductor dies 244′. The dummy die 208 can be formed from a singulation process on a dummy silicon wafer which is coupled to the first plurality of semiconductor dies 244 and a second plurality of semiconductor dies 244′. As shown in FIG. 2, the dummy die 208 can be bonded to the first and second pluralities of semiconductor dies 244 and 244′ through dielectric-dielectric bonding (e.g., SiO—SiO bonding) between the dielectric layers 218 and 218′. The dielectric layers 218 and 218′ can be made of dielectric materials including silicon oxide, silicon nitride, and/or silicon carbon nitride. In this example, each one of the dielectric layers 218 and 218′ may have a thickness ranging from 10 nm to 1 μm. In some other examples, the dielectric layers 218 and 218′ can be different to the dielectric materials 220. For example, dielectric layer 218 (e.g., silicon nitride) can be deposited above the back side surfaces of the first plurality of semiconductor dies 244 and the second plurality of semiconductor dies 244′. In addition, the dielectric layer 218′ (e.g., silicon nitride) can be deposited on the front side surface of the dummy silicon wafer before the wafer-to-wafer bonding. The dielectric layers 218 and 218′ can be bonded together through applying thermal treatment and compression pressure. Fusion bonding can be formed between the dielectric layers 218 and 218′ to provide strong adhesion between the dummy die 208 and the first and second pluralities of semiconductor dies 244 and 244′. In comparison to the NCF layer 118 disposed between the dummy die 108 and stacked semiconductor dies 144 and 144′, the fusion bonded dielectric layers 218 and 218′ described in FIG. 2 has a much less thickness and high thermal conductivity (e.g., thermal conductivity of silicon oxide is close to 1.2 W/(m·K). As a result, the semiconductor device 200 may present a better heat mitigation performance compared to that of semiconductor device 100.

The semiconductor device 200 may include any number of semiconductor dies in the stacked semiconductor dies. For example, each one of the pluralities of stacked semiconductor dies 244 and 244′ may include three or more semiconductor dies that are vertically coupled to each other. The additional semiconductor dies may be stacked through a similar technique to that described with respect to the first plurality and second plurality of stacked semiconductor dies 244 and 244′. The semiconductor device 200 may further include encapsulating material 236 (e.g., mold resin compound or the like) that at least partially encapsulates the dummy die 208, the pluralities of stacked semiconductor dies 244 and 244′, the corresponding logic die 242, and the substrate 230 to prevent electrical contact therewith, and provide mechanical strength and protection to the semiconductor device 200.

Although illustrated in a particular configuration, a semiconductor device of the present technique could include a different configuration than shown in FIG. 2. For example, a semiconductor device could include a different number of stacks of semiconductor dies, a different number of pluralities of stacked semiconductor dies within each stack, a different number of semiconductor dies within each stack, a different number of semiconductor dies within each plurality of stacked semiconductor dies, and so on. In one embodiment, the semiconductor device 200 can include 4, 6, 8, 10 or any number therebetween stacks of semiconductor dies. In another embodiment, the semiconductor device 200 can include 10, 20, 50, 100, 200, 300, 400, 500, or any number therebetween stacks of semiconductor dies. In another embodiment, the semiconductor device 200 can be a two-crossbar random access memory (TCRAM), having 6 or more stacked semiconductor memory dies disposed on a logic die.

In one embodiment, various number of memory dies, e.g., 4, 8, 16, 32, 48, 96, 128, 256, 512 or any number there between can be vertically stacked on top of each other to form a high bandwidth memory (HBM) with increased memory bandwidth. These memory dies may be interconnected using TSVs, which enables high speed communication between the memory dies. Specifically, a single stack of functional dies (e.g., DRAM dies) in the above noted front-to-back stacking configuration can be surrounded by dielectric material. In the single stack of functional dies, the back surface of the top functional die (e.g., a top DRAM die) can be coupled to a dummy silicon die by fusion bonding the dielectric layer disposed on the back surface of the top functional die and the front surface of the Silicon layer.

Semiconductor device 200 illustrates one type of device of the present technology. Alternatively, a front side surface of the dummy silicon die can be bonded with front side surfaces of a plurality of memory stacks. In one embodiment, a logic die's front side surface can be coupled to the front side surface of a plurality of stack functional memory dies (e.g., a plurality of stack of DRAM dies). Each of the plurality of stack functional dies is in a B2F stacking configuration. The plurality of stack functional dies can be surrounded by dielectric material such as SiO₂. The front side surface of the top functional dies within each of the plurality of stack functional dies can be coupled to a front side of the Silicon layer by fusion bonding the SiO₂ layers disposed on the front side of the top functional dies (e.g., top DRAM dies) and front side of the Silicon layer.

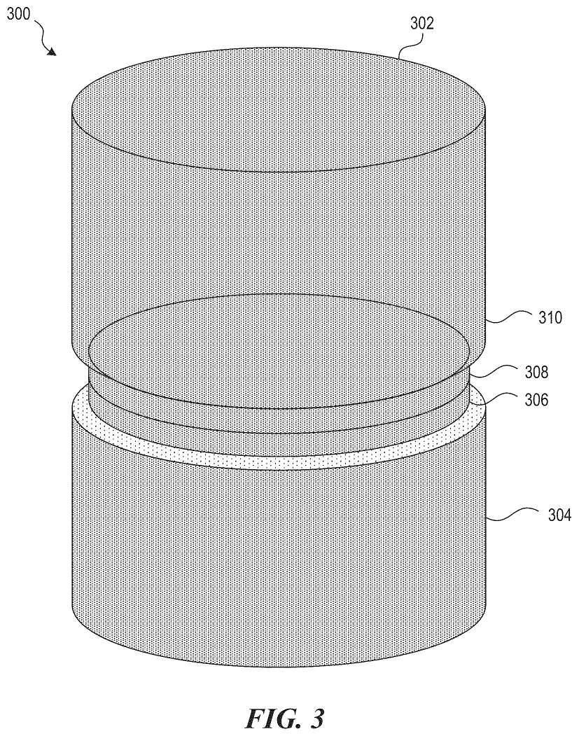

This disclosure now turns to a series of steps for fabricating the semiconductor device 200 in accordance with embodiments of the present technology. Specifically, FIGS. 3-9B illustrate simplified schematic perspective and cross-sectional views of a series of steps for fabricating semiconductor devices (e.g., the semiconductor device 200 shown in FIG. 2) in accordance with an embodiment of the present technology. The steps are illustrated with respect to specific embodiments for ease of description. However, the steps described with respect to FIGS. 3-9B could be performed to fabricate semiconductor devices in accordance with other embodiments.

Beginning with FIG. 3 at stage 300, a stack of semiconductor wafers 302 is provided. The stack of semiconductor wafers 302 can be adhered to a carrier wafer 304 to enable the semiconductor wafers to withstand processing. For example, a first semiconductor wafer 306 can be adhered to the carrier wafer 304 (e.g., in a face down arrangement). TSVs may be exposed at a back side of the first semiconductor wafer 306, and contact pads may be disposed thereat. A second semiconductor wafer 308 may be electrically coupled to the first semiconductor wafer 306 at the contact pads through wafer-wafer bonding (e.g., in a front-to-back arrangement). The second semiconductor wafer 308 may be electrically coupled to the first semiconductor wafer 306 through hybrid bonding to bond the wafers through a dielectric material (e.g., dielectric block) and metal-metal interconnects. A third semiconductor wafer 310 may be coupled to the second semiconductor wafer 308 at contact pads on the back side of the second semiconductor wafer 308. The third semiconductor wafer 310 may be thicker than each of the other semiconductor wafers. In aspects, each of the plurality of semiconductor wafers may have a similar arrangement of semiconductor dies. The stack of semiconductor wafers 302 may then be removed from the carrier wafer 304 for further processing. In some other embodiments, the stack of semiconductor wafers 302 may include more than two semiconductor wafers (e.g., three semiconductor wafers, or four semiconductor wafers) that are electrically coupled. These more than two semiconductor wafers may be also disposed under and coupled to the third semiconductor wafer 310.

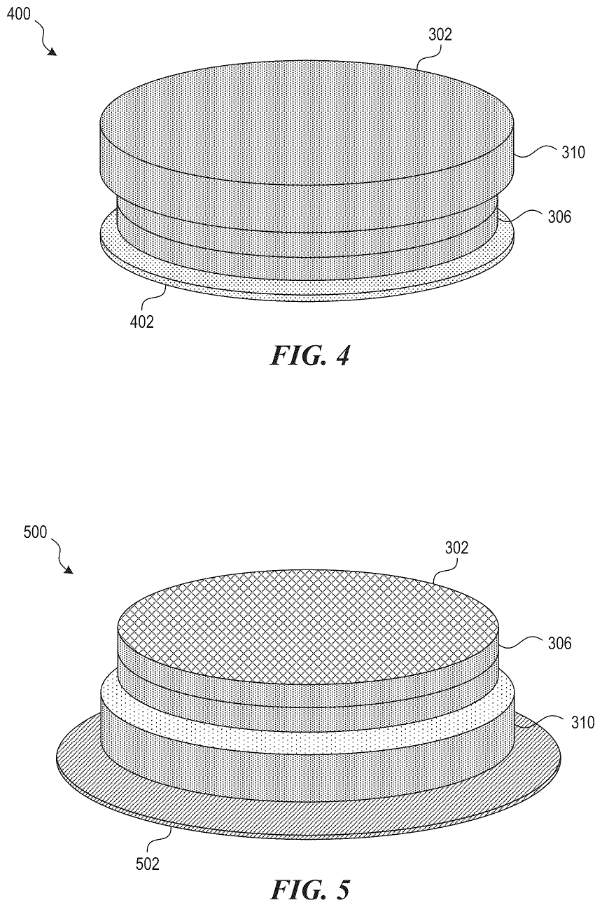

Turning to FIG. 4 at stage 400, the stack of semiconductor wafers 302 can be adhered to a back grinding tape 402 to enable the stack of semiconductor wafers 302 to be thinned. The first semiconductor wafer 306 may be adhered to back grinding tape 402 in a face down position so that the back side of the third semiconductor wafer 310 is exposed for thinning. Here, the back side of the third semiconductor wafer 310 can be thinned through any appropriate method, for example, using back grinding, chemical-mechanical planarization (CMP), or the like. In aspects, the back grinding process may not expose TSVs at the back side of the third semiconductor wafer 310. After thinning, the back grinding tape 402 can be removed from the stack of semiconductor wafers 302 to enable the stack of semiconductor wafers 302 to be diced.

Turning to FIG. 5 at stage 500, the stack of semiconductor wafers 302 can be diced into multiple pluralities of stacked semiconductor dies. The stack of semiconductor wafers 302 may be adhered to dicing tape 502 at the back side of the third semiconductor wafer 310. The back side of the first semiconductor wafer 306 may be exposed to enable the stack of semiconductor wafers 302 to be diced between the plurality of semiconductor dies. Once diced, the multiple pluralities of stacked semiconductor dies may be singulated from one another. The multiple pluralities of stacked semiconductor dies may then be tested and assembled into packages.

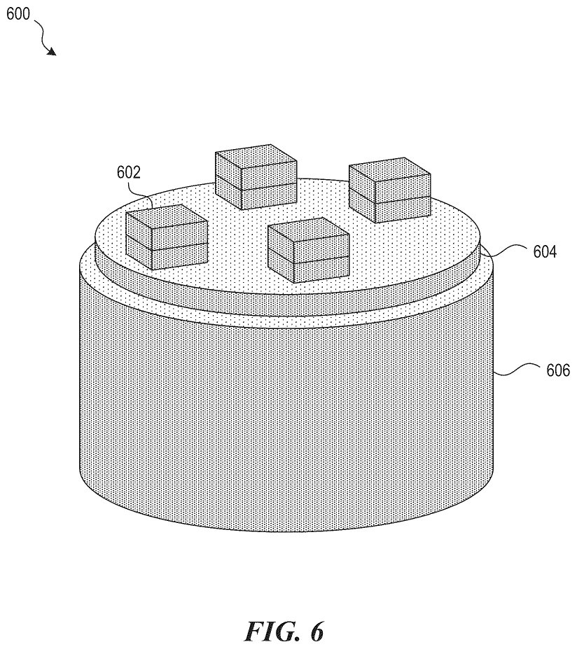

Turning next to FIG. 6 at stage 600, the multiple pluralities of stacked semiconductor dies 602 are assembled onto a wafer of semiconductor dies 604 (e.g., logic dies). Here, each of the multiple pluralities of stacked semiconductor dies 602 may have a same quantity of semiconductor dies (e.g., two semiconductor dies in each stack). In some other embodiments, the multiple pluralities of stacked semiconductor dies 602 may have different quantities of semiconductor dies. For example, the multiple pluralities of stacked semiconductor dies 602 may each have three semiconductor dies. In some other examples, the multiple pluralities of stacked semiconductor dies 602 may each have up to ten or twenty semiconductor dies. The pluralities of stacked semiconductor dies 602 may be electrically coupled to the wafer of semiconductor dies 604 at respective semiconductor dies or at the same semiconductor die (e.g., at different lateral locations) using chip-wafer bonding. The wafer of semiconductor dies 604 may be assembled onto a carrier wafer 606 to enable the semiconductor device assembly to withstand processing. The wafer of semiconductor dies 604 may have a different arrangement of semiconductor dies from the multiple pluralities of stacked semiconductor dies 602. The pluralities of stacked semiconductor dies 602 may be selected from the stacked semiconductor dies diced from the stack of semiconductor wafers. The pluralities of stacked semiconductor dies 602 may be selected based on a quality of the pluralities of stacked semiconductor dies 602. The quality of the pluralities of stacked semiconductor dies 602 may be determined by probing the stacked semiconductor dies diced from the stack of semiconductor wafers. In this way, the highest quality stacks of semiconductor dies, or “known good cubes,” may be selected from the stacked semiconductor dies diced from the stack of semiconductor wafers to improve yield.

In some cases, the wafer of semiconductor dies 604 can be diced to produce a single stack of semiconductor dies (e.g., a HBM device), as illustrated in FIG. 6. In other cases, the wafer of semiconductor dies 604 can be diced to produce a semiconductor die (e.g., of the wafer of semiconductor dies 604) with multiple stacks of semiconductor dies coupled therewith at multiple lateral locations. For example, the semiconductor device can include a central processing unit (CPU) or graphics processing unit (GPU) with a plurality of memory die stacks coupled therewith. Specifically, a three dimensional integration of semiconductor device can include stacked DRAM die and workstation GPUs in a same package.

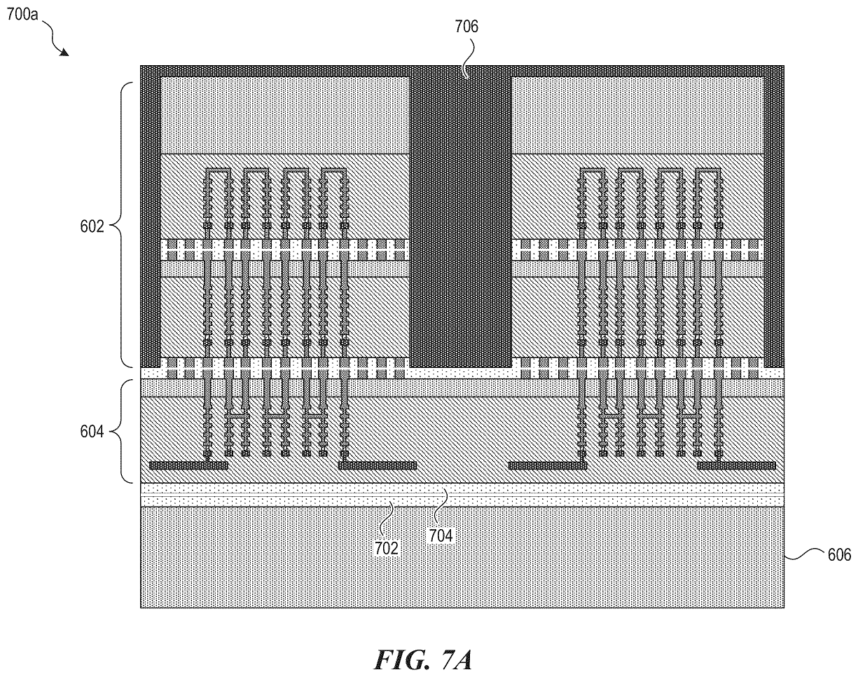

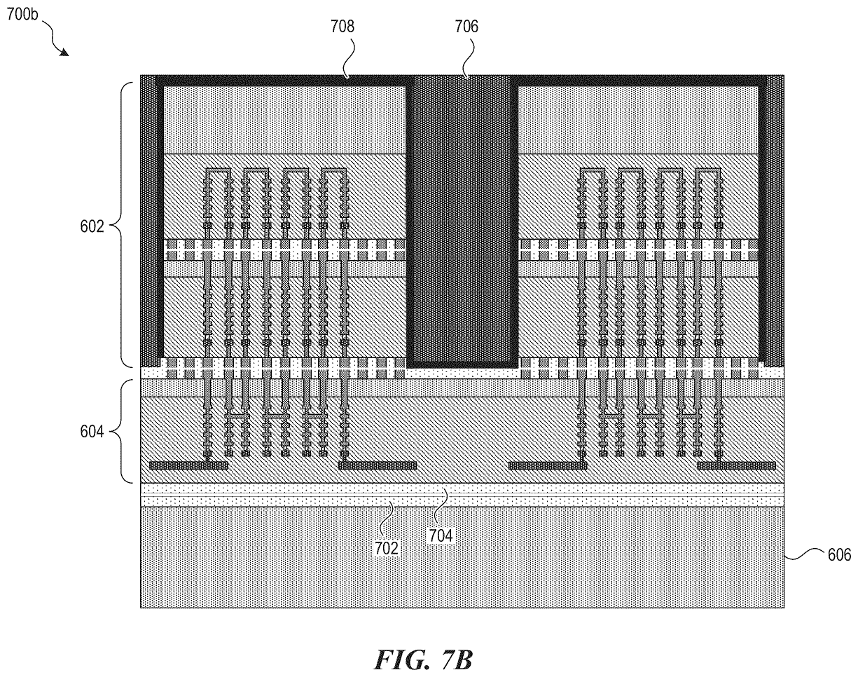

Turning next to FIG. 7A at stage 700a, a dielectric material 706 (e.g., silicon oxide) may be deposited between the pluralities of stacked semiconductor dies 602. Each one of the pluralities of stacked semiconductor dies 602 may include two or more semiconductor dies vertically coupled through corresponding contact pads and interconnections. In aspects, the dielectric material layer 702 may be also disposed on the logic wafer 604. Further, the dielectric material 706 may be disposed over back side surfaces of the pluralities of stacked semiconductor dies 602. Further, the dielectric material 706 can surround sidewalls of the pluralities of stacked semiconductor dies 602. In this way, the pluralities of stacked semiconductor dies 602 may be embedded in the dielectric material 706. The pluralities of stacked semiconductor dies 602 may be disposed at various locations at the back side surface of the logic wafer 604. The distance D1 between adjacent pluralities of stacked semiconductor dies 602 may range from 10 μm to 10 mm. In this example, the aspect ratio of the space filled by the dielectric material 706 (e.g., a ratio of height of pluralities of stacked semiconductor dies 602 to the distance D1) may be up to 20:1. A gap fill dielectric deposition process can be used to fill the space between adjacent pluralities of stacked semiconductor dies 602, such as chemical vapor deposition (CVD), physical vapor deposition (PVD), or atomic layer deposition (ALD). Specifically, a high density plasma assisted chemical vapor deposition (HDPCVD) technique can be used for the dielectric gap fill.

In some implementations, each of the pluralities of stacked semiconductor dies 602 may be coupled to a dedicated logic die of the logic wafer 604. Accordingly, the dielectric material 706 may be disposed on the carrier wafer 606. As shown, the carrier wafer 606 can be coupled with the logic wafer 604 through fusion bonding between dielectric layers 702 and 704. In this example, the dielectric material 706 may then be thinned, using a CMP process, to provide a planar dielectric layer above back side surfaces of the pluralities of stacked semiconductor dies 602, at which additional dummy wafer or dies can be coupled. The thickness of the dielectric layer above the pluralities of stacked semiconductor dies 602 can be adjusted by controlling the CMP process (e.g., using an end point detection technique for CMP process), and may range from 10 nm to 1 μm. In this example, dielectric materials having low thermal resistance can be utilized as the dielectric material 706. For example, silicon oxide has a high thermal conductivity around 1.2 W/(m-K), therefore can be used as the gap fill material to improve thermal conductance of the semiconductor device described in the present disclosure.

Alternatively, a liner layer 708 can be deposited before filling dielectric material 706 between the pluralities of stacked semiconductor dies 602. As shown in FIG. 7B at stage 700b, the liner layer 708 can be conformally deposited above the semiconductor device incoming from stage 600. For example, the liner layer 708 can be deposited above back side surfaces and sidewalls of the pluralities of stacked semiconductor dies 602. In addition, the liner layer 708 may be also deposited above the logic wafer 604 and between adjacent pluralities of stacked semiconductor dies 602. The liner layer 708 can be made of materials different to the dielectric material 706, such as silicon nitride. Various thin film deposition techniques including CVD, PVD, and ALD can be utilized here to conformally deposited the liner layer 708. A thickness of the liner layer 708 may range from 10 nm to 1 μm. Once the liner layer 708 is deposited, the dielectric material 706 can be coated above the back side surfaces of and in space between adjacent pluralities of stacked semiconductor dies 602. The dielectric material 706 can be further planarized using the CMP process. In this example, the planarization of dielectric material 706 can be stopped on the liner layer 708 disposed above back side surfaces of the pluralities of stacked semiconductor dies 602.

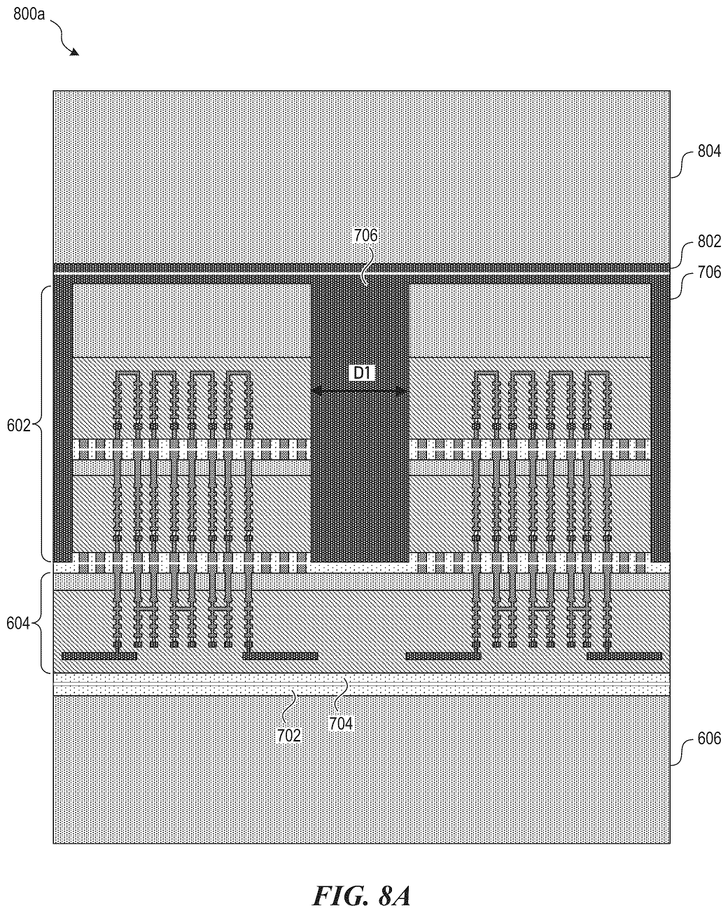

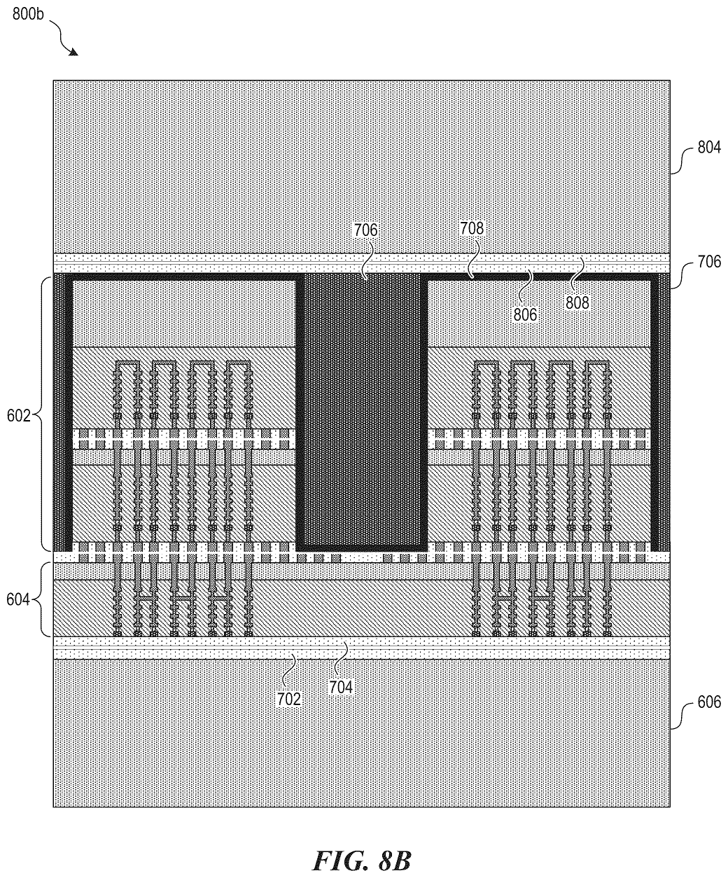

Turning next to FIG. 8A at stage 800a, a dummy wafer can be bonded with the semiconductor wafer assembly incoming from stage 700a. In aspects, a front side surface of a dummy silicon wafer 804 can be boned with a back side surface of the chip to wafer bonded assembly described in FIG. 7A. The dummy silicon wafer 804 can be boned using a wafer-to-wafer face-to-back fusion bonding process. For example, a dielectric layer 802 made of dielectric material 706 (e.g., silicon oxide) can be coated on the front side surface of the dummy silicon wafer 804. The dummy silicon wafer 804 can be bonded to the chip on wafer assemble through forming fusion bonding between the dielectric layer 802 and the planar layer of 706 disposed above back side surfaces of the pluralities of stacked semiconductor dies 602. In this example, the fusion bonding processes rely on chemical bonds and interactions between interfacing surfaces of the dielectric layers 802 and 706. For example, intermolecular interactions including van der Waals forces, hydrogen bonds, and strong covalent bonds can be formed in the fusion bonding process to join dielectric-dielectric surfaces at high temperatures and/or compression pressures. Further, the bonding interface between the dummy silicon wafer 804 and chip on wafer assembly may be affected by thermal cycles, e.g., anneal temperatures, that are applied during the fusion bonding process. The fusion bonding technique can help semiconductor die manufacturers meet demands for a reduction in the volume occupied by semiconductor die assemblies.

Alternatively, dielectric layers made of materials different to the dielectric material 706 can be deposited to assist bonding a dummy wafer to the chip on wafer assembly incoming from stage 700b. In aspects, once the dielectric material 706 is planarized and expose the liner layer 708 above the back side surfaces of the pluralities of stacked semiconductor dies 602, a dielectric layer 806 can be deposited above the planarized dielectric material 706 and the exposed liner layer 708. The dielectric layer 806 may be made of materials (e.g., silicon nitride or silicon carbon nitride) different to the dielectric material 706 (e.g., silicon oxide). In addition, another dielectric layer 808 can be coated on the front side surface of the dummy silicon wafer 804. The dielectric layer 808 can be made of materials same to the dielectric layer 806 (e.g., silicon nitride or silicon carbon nitride). Each of the dielectric layers 806 and 808 may have a thickness ranging from 100 nm to 1 μm. In this example, the dummy silicon wafer 804 can be bonded to the chip on wafer assembly through fusion bonding the dielectric layers 806 and 808. Compression pressures and/or thermal annealing processes may be applied in this example to achieve high strength dielectric-dielectric bonding (e.g., SiCN—SiCN fusion bond) between the dummy silicon wafer 804 and the pluralities of stacked semiconductor dies 602.

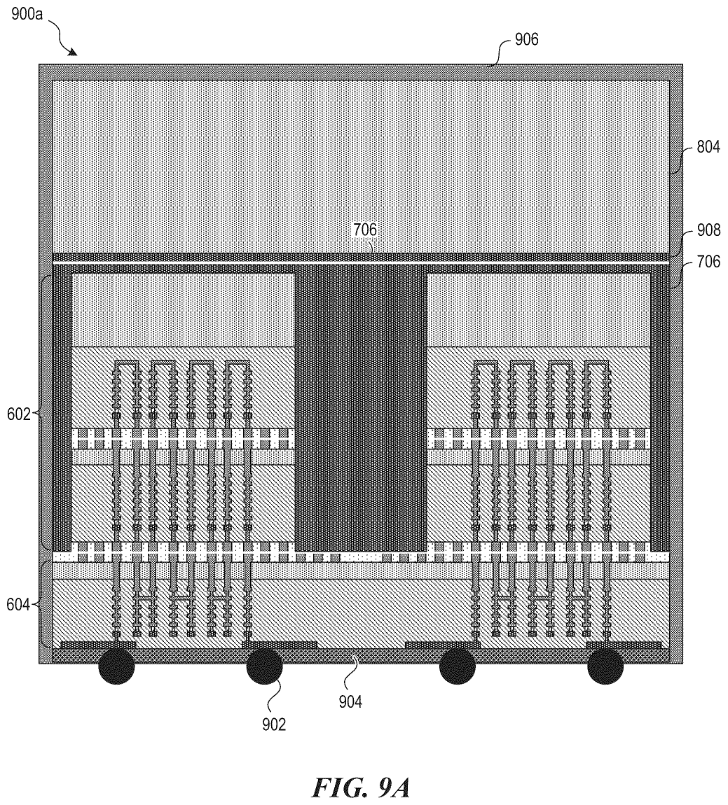

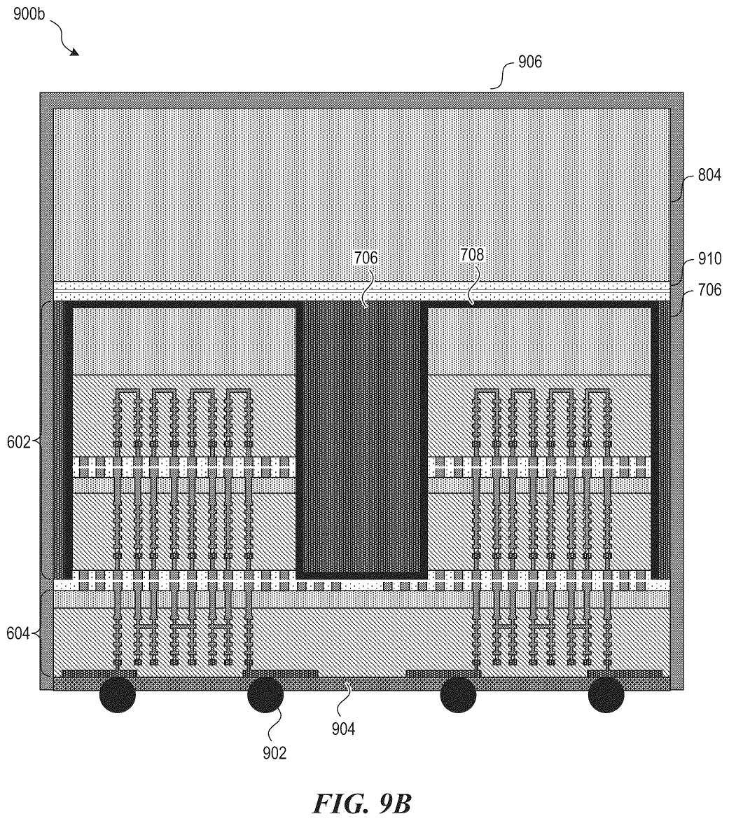

FIG. 9A illustrates a simplified schematic semiconductor device fabrication stage 900a in accordance with an embodiment of the present technology. As shown, the carrier wafer 606 incoming from stage 800a can be removed from the semiconductor device using a backside polishing or wafer grinding process. In addition, the semiconductor device assembly including dummy wafer 804, pluralities of stacked semiconductor dies 602, and logic wafer 604 can be assembled onto a package-level substrate 904 (e.g., printed circuit board (PCB), semiconductor substrate, etc.). Here, one or more pluralities of stacked semiconductor dies 602 may be singulated through the dummy wafer 804, dielectric material 706 and logic die 604. Dielectric material 706 may surround the one or more singulated plurality of stacked semiconductor dies for electrical isolation. In this example, the dummy silicon die 804 can be bonded with the corresponding plurality of stacked semiconductor dies through a dielectric layer 908, which is formed through fusion bonding of dielectric layers 706 and 802 on stage 800a. The dielectric layer 908 may have a thickness ranging from 100 nm to 1 μm. Here, the dielectric layer 908 disposed between the stacked semiconductor dies 602 and dummy die 804 can be extremely thinner than a NCF layer (e.g., having a thickness at around 15 μm) described in FIG. 1 and used in conventional semiconductor device assembly. Therefore, the semiconductor device shown in FIG. 9A can provide an enhanced thermal conduction performance.

As shown in FIG. 9A, the substrate 904 can further include package-level contact pads that provide external connectivity (e.g., via solder balls 902) to the pluralities of stacked semiconductor dies 602 and corresponding logic dies 604 (e.g., power, ground, and I/O signals) through traces, lines, vias, and other electrical connection structures in the substrate 904 that electrically connect the package-level contact pads to contact pads at an upper surface of the substrate 904. The semiconductor device can further include an encapsulant material 906 (e.g., mold resin compound or the like) that at least partially encapsulates the dummy wafer die 804, the stack of semiconductor dies 602, the corresponding logic die 604, and the substrate 904 to prevent electrical contact therewith and provide mechanical strength and protection to the semiconductor device.

Turning next to FIG. 9B at stage 900b, the stacked semiconductor dies can be assembled in a semiconductor device. In aspects, the carrier wafer 606 can be removed from the front side of the logic wafer 604. Additionally, the semiconductor device assembly including dummy wafer 804, one or more pluralities of stacked semiconductor dies 602, the liner layer 708, and the logic wafer 604 can be assembled onto a package-level substrate 904 (e.g., printed circuit board (PCB), semiconductor substrate, etc.). In this example, the dummy silicon die 804 can be bonded with the corresponding plurality of stacked semiconductor dies through a dielectric layer 910, which is formed through fusion bonding of dielectric layers 806 and 808 at stage 800b. The dielectric layer 910 may have a thickness ranging from 100 nm to 1 μm. Here, the dielectric layer 910 disposed between the stacked semiconductor dies 602 and dummy die 804 can be extremely thinner than the NCF layer included in conventional semiconductor device assembly. Therefore, the semiconductor device shown in FIG. 9B can present an enhanced thermal conduction performance.

At stage 900b, the one or more pluralities of stacked semiconductor dies 602 may be singulated through the dummy wafer 804, dielectric material 706, liner layer 708, and logic die 604. Dielectric material 706 may surround the liner layer 708 disposed on sidewalls of one or more singulated plurality of stacked semiconductor dies for electrical isolation. In this example, the substrate 904 can further include package-level contact pads that provide external connectivity (e.g., via solder balls 902) to the pluralities of stacked semiconductor dies 602 and corresponding logic dies 604. Moreover, the semiconductor device can further include the encapsulant material 906 that encapsulates the dummy wafer die 804, the stack of semiconductor dies 602, the corresponding logic die 604, and the substrate 904 to prevent electrical contact therewith and provide mechanical strength and protection to the semiconductor device.

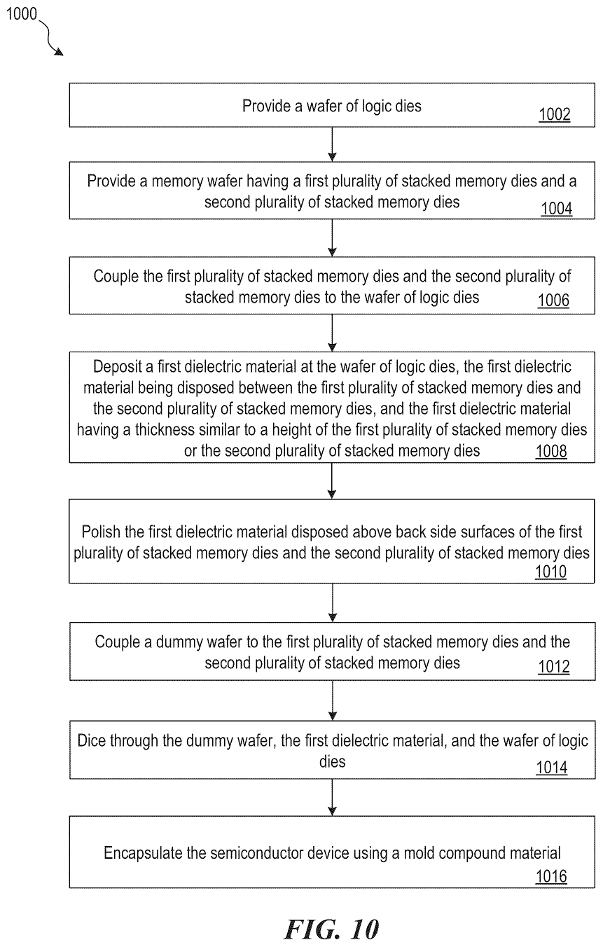

Turning to FIG. 10 which is a flow chart illustrating a method 1000 of processing a semiconductor memory device according to embodiments of the present technology. The method 1000 includes providing a wafer of logic dies, at 1002. For example, the wafer of logic dies 604 can be provided for the semiconductor device assembly. Particularly, the logic dies included in wafer 604 can be diced to produce a single stack of semiconductor dies for HBM device application, or to produce a semiconductor die with multiple stacks of other semiconductor dies couple therewith at various lateral locations.

In addition, the method 1000 includes providing a memory wafer having a first plurality of stacked memory dies and a second plurality of stacked memory dies, at 1004. For example, multiple pluralities of stacked semiconductor dies 602 can be provided for the semiconductor device assembly. Each one of the pluralities of stacked semiconductor dies can be coupled to adjacent semiconductor dies through interconnections and contact pads for electrical connection. In addition, each plurality of stacked semiconductor dies may include two or more semiconductor dies that are vertically coupled in corresponding stack.

The method 1000 also includes coupling the first plurality of stacked memory dies and the second plurality of stacked memory dies to the wafer of logic dies, at 1006. For example, the pluralities of stacked semiconductor dies 602 can be electrically coupled to the wafer of semiconductor dies 604 at respective semiconductor dies or at a same semiconductor die (e.g., at different lateral locations) using a chip-wafer bonding technique, as shown in FIG. 6.

Further, the method 1000 includes depositing a first dielectric material at the wafer of logic dies, the first dielectric material being disposed between the first plurality of stacked memory dies and the second plurality of stacked memory dies, and the first dielectric material having a thickness similar to a height of the first plurality of stacked memory dies or the second plurality of stacked memory dies, at 1008. For example, the dielectric material 706 can be deposited between the pluralities of stacked semiconductor dies 602. The dielectric material 706 can be disposed above back side surfaces of the pluralities of stacked semiconductor dies 602 and surround sidewalls of the pluralities of stacked semiconductor dies 602. The dielectric material 706 may have a thickness similar to a height of the pluralities of stacked semiconductor dies 602. The dielectric material 706 can also be disposed above the logic wafer 604, as shown in FIG. 7A. In some other examples, a liner 708 may be conformally coated above the pluralities of stacked semiconductor dies 602 and on the logic die 604. As shown in FIG. 7B, the dielectric material 706 can further deposited above the liner layer 708.

The method 1000 also includes polishing the first dielectric material disposed above back side surfaces of the first plurality of stacked memory dies and the second plurality of stacked memory dies, at 1010. For example, a CMP process can be utilized to planarize the dielectric material 706 disposed above the back side surfaces of the pluralities of stacked semiconductor dies 602. As shown in FIG. 7A, a planar dielectric layer 706 can be formed with a thickness ranging from 10 nm to 1 μm. In another example and as shown in FIG. 7B, the dielectric material 706 can be polished until exposing the underlying dielectric liner layer 708. Here, the liner layer 708 disposed above the back side surfaces of the pluralities of stacked semiconductor dies 602 may perform as a polishing stop layer and is coplanar with the polished dielectric material 706.

Moreover, the method 1012 includes coupling a dummy wafer to the first plurality of stacked memory dies and the second plurality of stacked memory dies, at 1012. For example, the dummy silicon wafer 804 can be coupled to the pluralities of stacked semiconductor dies 602 through fusion bonding between the dielectric layer 802 and the planar layer 706, as described in FIG. 8A. In another example, the dielectric layers 806 and 808 can be respectively deposited above the exposed liner layer 708 and the back side surface of the dummy silicon wafer 804, respectively. Further, the dummy silicon wafer 804 can be coupled to the pluralities of stacked semiconductor dies 602 through fusion bonding (e.g., SiCN—SiCN fusion bonding) between the dielectric layers 806 and 808.

The method 1000 also includes dicing through the dummy wafer, the first dielectric material, and the wafer of logic dies, at 1014. For example, one or more pluralities of stacked semiconductor dies 602 may be singulated by a wafer dicing process, e.g., dicing through the dummy silicon wafer 804, dielectric layer 706, and the logic wafer 604. In addition, the carrier wafer 606 may be removed by a wafer grinding or polishing process. The singulated one or more pluralities of stacked semiconductor dies 602 can be assembled onto the package-level substrate 904 that provide external connectivity via solder balls 902.

Lastly, the method 1000 includes encapsulating the semiconductor device using a mold compound material, at 1016. For example, the encapsulant material 906 can be applied to at least partially encapsulate the dummy wafer die 804, the one or more pluralities of stacked semiconductor dies 602, the corresponding logic die 604, and the substrate 904, in order to prevent electrical contact therewith and provide mechanical strength and protection to the semiconductor device in the present disclosure.

Although in the foregoing example embodiment semiconductor device assemblies have been illustrated and described as including a particular configuration of semiconductor dies, in other embodiments, assemblies can be provided with different configurations of semiconductor dies. For example, the semiconductor device assemblies illustrated in any of the foregoing examples could be implemented with, for example, a vertical stack of semiconductor dies, a plurality of semiconductor dies, a single semiconductor die, mutatis mutandis.

In accordance with one aspect of the present disclosure, the semiconductor devices illustrated in the assemblies of FIGS. 1-10 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could include memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

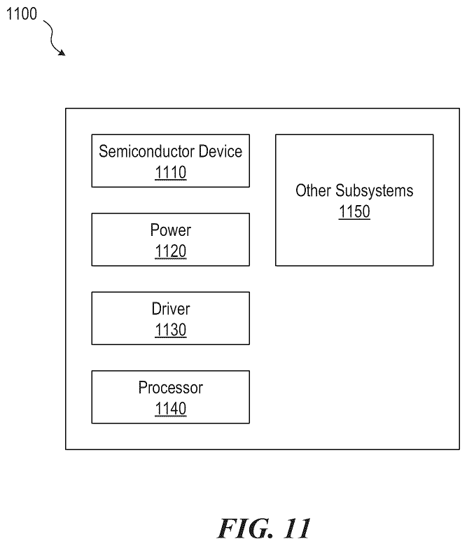

Any one of the semiconductor devices and semiconductor device assemblies described above with reference to FIGS. 1-10 can be incorporated into any of a myriad of larger and/or more complex systems, a representative example of which is system 1100 shown schematically in FIG. 11. The semiconductor die stack as provided in FIGS. 1-10 can communicate with one or more devices within the system 1100 using one or more standard protocols. For example, the stacked semiconductor dies may communicate using a HBM protocol. Alternatively, the stacked semiconductor dies may communicate using a suitable protocol. The system 1100 can include a semiconductor device 1110 (e.g., a discrete semiconductor device), a power source 1120, a driver 1130, a processor 1140, and/or other subsystems or components 1150. The semiconductor device 1110 can include features generally similar to those of the semiconductor device assemblies described above with reference to FIGS. 1-10. The resulting system 1100 can perform any of a wide variety of functions, such as memory storage, data processing, and/or other suitable functions. Accordingly, representative systems 1100 can include, without limitation, hand-held devices (e.g., mobile phones, tablets, digital readers, and digital audio players), computers, vehicles, appliances and other products. Components of the system 1100 may be housed in a single unit or distributed over multiple, interconnected units (e.g., through a communications network). The components of the system 1100 can also include remote devices and any of a wide variety of computer readable media.

Specific details of several embodiments of semiconductor devices, and associated systems and methods, are described above. Depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, CMP, or other suitable techniques.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a PCB or wafer-level substrate, a die-level substrate, or another die for die-stacking or 3DI applications.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device, comprising:
a logic die;
a first plurality of stacked memory dies electrically coupled with the logic die at a first location above a back side surface of the logic die;
a second plurality of stacked memory dies electrically coupled with the logic die at a second location above the back side surface of the logic die;
a first dielectric material disposed above the back side surface of the logic die and between the first plurality of stacked memory dies and the second plurality of stacked memory dies, the first dielectric material having a thickness similar to a height of the first plurality of stacked memory dies or the second plurality of stacked memory dies; and
a dummy die disposed above the first dielectric material and coupled to the first plurality of stacked memory dies and the second plurality of stacked memory dies, wherein the dummy die is coupled to back side surfaces of the first plurality and the second plurality of stacked memory dies through a second dielectric layer having dielectric-dielectric fusion bonding.

2. The semiconductor device of claim 1, wherein the first dielectric material is silicon oxide, and the second dielectric layer is made of silicon oxide.

3. The semiconductor device of claim 1, wherein the second dielectric layer is made of materials different to the first dielectric material.

4. The semiconductor device of claim 3, wherein the first dielectric material is silicon oxide, and the second dielectric layer is made of materials including silicon nitride, and/or silicon carbon nitride.

5. The semiconductor device of claim 1, further comprising a third dielectric layer disposed on sidewalls and back side surfaces of the first plurality and the second plurality of stacked memory dies, wherein the third dielectric layer is made of silicon nitride.

6. The semiconductor device of claim 1, wherein the second location is away from the first location by a distance, and the distance ranges from 10 μm to 10 mm.

7. The semiconductor device of claim 1, wherein each of the first plurality and the second plurality of stacked memory dies includes a top memory die and a plurality of core memory dies, the top memory die being disposed above the plurality of core memory dies, and the top memory die being thicker than each one of the plurality of core memory dies.

8. The semiconductor device of claim 7, wherein each of the first plurality and the second plurality of stacked memory dies includes interconnects coupling the top memory die and the plurality of core memory dies, and the interconnects electrically coupled between contact pads of adjacent memory dies of the top memory die and the plurality of core memory dies.

9. The semiconductor device of claim 1, wherein the first dielectric material is further disposed in edge region of the semiconductor device, and the first dielectric material surrounds outer sidewalls of the first plurality and the second plurality of stacked memory dies facing towards the edge region of the semiconductor device.

10. The semiconductor device of claim 1, further comprising an encapsulant material disposed above a back side surface and sidewalls of the dummy die, the encapsulant material horizontally extending to surround sidewalls of the first plurality and the second plurality of stacked memory dies and sidewalls of the logic die.

11. A semiconductor device, comprising:
a logic die;
a plurality of stacked memory dies electrically coupled with the logic die;
a first dielectric material disposed around the plurality of stacked memory dies, the first dielectric material having a thickness similar to a height of the plurality of stacked memory dies; and
a dummy die disposed above the plurality of stacked memory dies, the dummy die being coupled with a back side surface of the plurality of stacked memory dies through a second dielectric layer having dielectric-dielectric bonding.

12. The semiconductor device of claim 11, wherein the first dielectric material and the second dielectric layer are made of a same dielectric material including silicon oxide.

13. The semiconductor device of claim 11, wherein the first dielectric material is silicon oxide, and the second dielectric layer is made of materials including silicon nitride, and/or silicon carbon nitride.

14. The semiconductor device of claim 11, further comprising a third dielectric layer disposed on sidewalls and back side surface of the plurality of stack memory dies, wherein the third dielectric layer is made of materials including silicon nitride.

15. The semiconductor device of claim 11, further comprising an encapsulant material disposed above a back side surface and sidewalls of the dummy die, the encapsulant material horizontally extending to surround sidewalls of the plurality of stacked memory dies and sidewalls of the logic die.

16. A method for fabricating a semiconductor device, comprising:
providing a wafer of logic dies;
providing a memory wafer having a first plurality of stacked memory dies and a second plurality of stacked memory dies;
coupling the first plurality of stacked memory dies and the second plurality of stacked memory dies to the wafer of logic dies;
depositing a first dielectric material at the wafer of logic dies, the first dielectric material being disposed between the first plurality of stacked memory dies and the second plurality of stacked memory dies, and the first dielectric material having a thickness similar to a height of the first plurality of stacked memory dies or the second plurality of stacked memory dies;
polishing the first dielectric material disposed above back side surfaces of the first plurality of stacked memory dies and the second plurality of stacked memory dies;
coupling a dummy wafer to the first plurality of stacked memory dies and the second plurality of stacked memory dies;
dicing through the dummy wafer, the first dielectric material, and the wafer of logic dies; and
encapsulating the semiconductor device using a mold compound material.

17. The method of claim 16, further comprising depositing, before coupling the dummy wafer, a second dielectric layer on a back side surface of the dummy wafer, wherein coupling the dummy wafer to the first plurality of stacked memory dies and the second plurality of stacked memory dies includes forming dielectric-dielectric fusion bonding between the first dielectric material and the second dielectric layer.

18. The method of claim 17, wherein the first dielectric material and the second dielectric layer are made of a same dielectric material including silicon oxide.

19. The method of claim 17, further comprising depositing, after polishing the first dielectric material, a third dielectric layer above the first dielectric material and the first plurality of stacked memory dies and the second plurality of stacked memory dies, the third dielectric layer and the second dielectric layer being made of a same second dielectric material that is different to the first dielectric material,
wherein the first dielectric material includes silicon oxide, the second dielectric layer is made of materials including silicon nitride and/or silicon carbon nitride, and
wherein coupling the dummy wafer to the first plurality of stacked memory dies and the second plurality of stacked memory dies includes forming dielectric-dielectric fusion bonding between the third dielectric layer and the second dielectric layer.

20. The method of claim 19, further comprising depositing, before depositing the first dielectric material, a fourth dielectric layer on sidewalls and back side surfaces of the first plurality and the second plurality of stacked memory dies, wherein the fourth dielectric layer is made of materials including silicon nitride, and the first dielectric material is disposed above the fourth dielectric layer.
